(19) United States
(12) Patent Application Publication
(10) Pub. No.: US 2012/0051011 A1
(43) Pub. Date: Mar. 1, 2012

(54) ELECTRONIC DEVICE WITH MODULAR JACK

(75) Inventor: Hiroshi OCHI, Osaka (JP)

(73) Assignee: FUNAI ELECTRIC CO., LTD., Osaka (JP)

(21) Appl. No.: 13/215,291

(22) Filed: Aug. 23, 2011

(30) Foreign Application Priority Data
Aug. 31, 2010 (JP) 2010-193472

(51) Int. Cl. H05K 5/00

(52) U.S. Cl. 361/752

(57) ABSTRACT

An electronic device includes a circuit board, a casing member, and a modular jack. The casing member accommodates the circuit board within the casing member. The casing member has an attaching part with a cavity. The modular jack has a pin electrode that is electrically connected to the circuit board. The modular jack is pivotally arranged relative to the attaching part of the casing member about a pivot axis between a rest position and an upright position. The modular jack is arranged within the cavity of the attaching part of the casing member when the modular jack is positioned at the rest position. The modular jack is arranged to protrude relative to the cavity of the attaching part of the casing member when the modular jack is positioned at the upright position.

### CROSS-REFERENCE TO RELATED APPLICATIONS

This application claims priority to Japanese Patent Application No. 2010-193472 filed on Aug. 31, 2010. The entire disclosure of Japanese Patent Application No. 2010-193472 is hereby incorporated herein by reference.

### BACKGROUND

1. Field of the Invention

The present invention generally relates to an electronic device. More specifically, the present invention relates to an electronic device with a modular jack.

2. Background Information

Recently, television receivers and other visual and audio devices and mobile devices have a function for connecting to a network. In such electronic devices with a network-connecting function, Ethernet® connection terminals are often used as the connectors for connecting to networks. Ethernet® connection terminals include RJ-45 modular jacks, and the opposing connectors have RJ-45 modular plugs. A modular jack known as RJ-45 has a shape resembling RJ-11, which is a modular jack used for phone lines. RJ-45 is slightly larger in size than RJ-11.

### SUMMARY

Notebook devices, card-type devices, and mobile devices in particular are becoming significantly thinner. It has been discovered that when these thin electronic devices are equipped with a RJ-45 modular jack in order to provide network connectivity, the height of the modular jack is greater than the thickness of the attaching part in the electronic device and the modular jack protrudes from the attaching part in the thickness direction of the electronic device. In other words, it has been discovered that when RJ-45 or another modular jack is attached to an electronic device, the size of the modular jack affects the size of a casing of an electronic device.

Specifically, the casing of the electronic device has been designed to avoid the modular jack to protrude from the attaching part such that the casing has a thickness that matches the height of the modular jack.

Furthermore, it has been proposed that locking means be provided to two locations in order to improve the reliability of a cable connector, and high-density installation be made possible by making the locking means thinner (see Japanese Laid-Open Patent Publication No. 2003-77585, for example).

It has also been proposed that a modular jack is used as the opposing connector for an RJ-45 modular plug (see Japanese Patent Publication No. 4143646, Published Japanese Translation No. 2004-503057 of the PCT International Publication, for example).

The present invention was conceived in light of the above-mentioned problems. One object of the present invention is to provide an electronic device in which the size of a casing member of the electronic device can become thinner even when the electronic device has a modular jack.

In accordance with one aspect of the present disclosure, an electronic device includes a circuit board, a casing member, and a modular jack. The casing member accommodates the circuit board within the casing member. The casing member has an attaching part with a cavity. The modular jack has a pin electrode that is electrically connected to the circuit board. The modular jack is pivotally arranged relative to the attaching part of the casing member about a pivot axis between a rest position and an upright position. The modular jack is arranged within the cavity of the attaching part of the casing member when the modular jack is positioned at the rest position. The modular jack is arranged to protrude relative to the cavity of the attaching part of the casing member when the modular jack is positioned at the upright position.

These and other objects, features, aspects and advantages will become apparent to those skilled in the art from the following detailed description, which, taken in conjunction with the annexed drawings, discloses a preferred embodiment.

### BRIEF DESCRIPTION OF THE DRAWINGS

Referring now to the attached drawings which form a part of this original disclosure:

FIG. 1 is a schematic perspective view of an electronic device according to one embodiment;

FIG. 2 is an exploded perspective view of an attaching part of a casing and a modular jack of the electronic device illustrated in FIG. 1;

FIG. 3 is a partial cross-sectional view of the modular jack taken along line in FIG. 2;

FIG. 4 is an enlarged cross-sectional view of the electronic device taken along C-C line in FIG. 1 illustrating a state in which a modular plug is inserted into the modular jack at a rest position;

FIG. 5 is an enlarged cross-sectional view of the electronic device taken along C-C line in FIG. 1 illustrating a state in which the modular jack is pivoted to an upright position;

FIG. 6 is an enlarged cross-sectional view of the electronic device taken along C-C line in FIG. 1 illustrating a state in which the modular jack slides relative to the casing and the modular plug while the modular jack is positioned at the upright position;

FIG. 7 is an enlarged cross-sectional view of the electronic device taken along C-C line in FIG. 1 illustrating a connection state between pin electrodes of the modular jack and the modular plug when the modular jack is positioned at the rest position as illustrated in FIG. 4;

FIG. 8 is an enlarged cross-sectional view of the electronic device taken along C-C line in FIG. 1 illustrating a connection state between the pin electrodes of the modular jack and the modular plug when the modular jack is positioned at the upright position as illustrated in FIG. 5;

FIG. 9 is an enlarged cross-sectional view of the electronic device taken along C-C line in FIG. 1 illustrating a connection state between the pin electrodes of the modular jack and the modular plug when the modular jack slides relative to the casing and the modular plug while the modular jack is positioned at the upright position as illustrated in FIG. 6; and

FIG. 10 is an exploded perspective view of an RJ-45 modular jack and modular plug.

### DETAILED DESCRIPTION OF EMBODIMENTS

A preferred embodiment will now be explained with reference to the drawings. It will be apparent to those skilled in the art from these disclosures that the following descriptions of the preferred embodiment are provided for illustration only and not for the purpose of limiting the invention as defined by the appended claims and their equivalents.

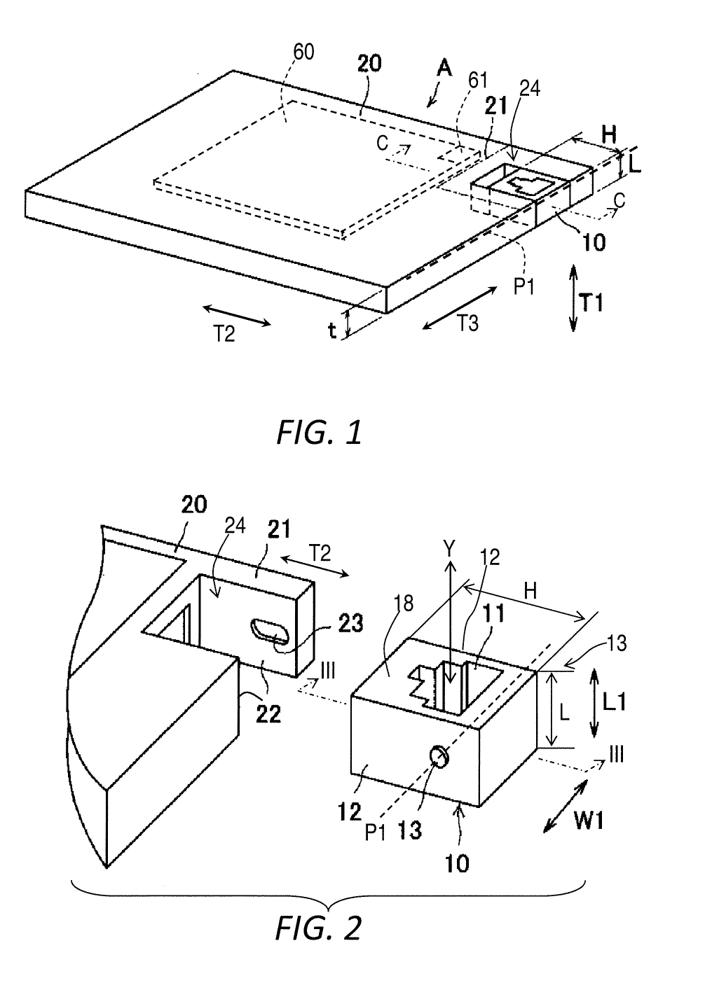

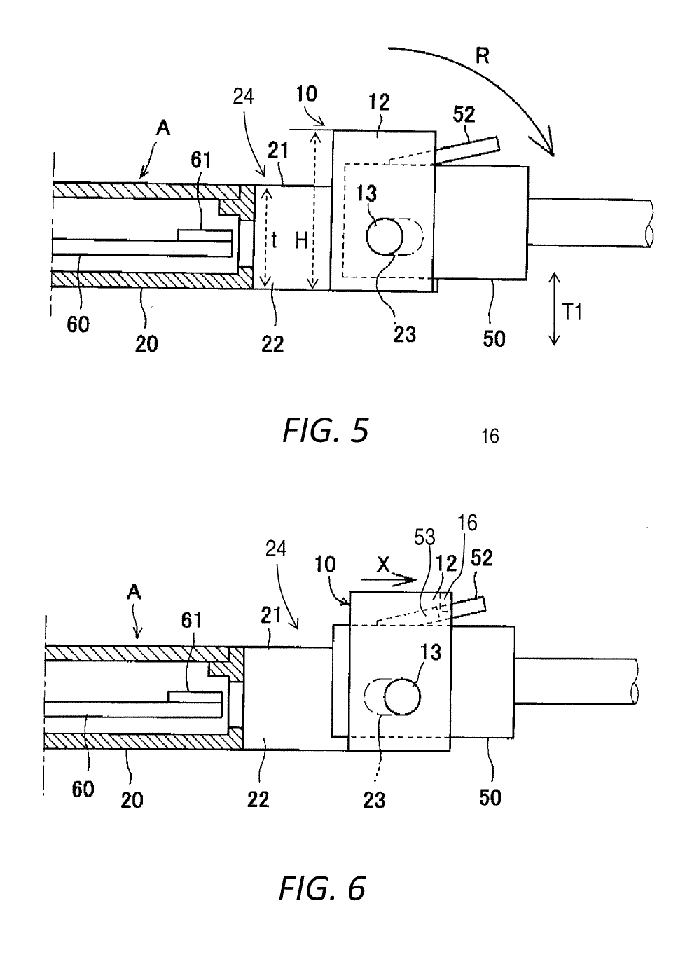

Referring to FIGS. 1-10, an electronic device A will be described in detail. As illustrated in FIG. 1, the electronic device A mainly includes a modular jack 10, a casing 20 (e.g., casing member), and a circuit board 60. The casing 20 accommodates the circuit board 60 within the casing 20. The casing 20 has an attaching part 21 with a cavity 24. The modular jack 10 is electrically connected to the circuit board 60. The modular jack 10 is pivotally arranged relative to the attaching part 21 of the casing 20 about a pivot axis P1 between a rest position as illustrated in FIG. 4 and an upright position as illustrated in FIGS. 5 and 6. The modular jack 10 is arranged within the cavity 24 of the attaching part 21 of the casing 20 when the modular jack 10 is positioned at the rest position as illustrated in FIG. 4. The modular jack 10 is arranged to protrude relative to the cavity 24 of the attaching part 21 of the casing 20 when the modular jack 10 is positioned at the upright position as illustrated in FIGS. 5 and 6.

The electronic device A is a card-type communication device. However, the electronic device A can be any other electronic devices having the modular jack 10 for communicating with electronic devices via a network.

As illustrated in FIG. 1, the casing 20 has a thickness t that is measured in a thickness direction T1 (e.g., first direction) of the electronic device A. Thus, the cavity 24 of the attaching part 21 also has a thickness (e.g., depth) in the thickness direction T1 of the electronic device A that is equal to the thickness t of the casing 20. The modular jack 10 has a height H that is measured in the thickness direction T1 of the electronic device A when the modular jack 10 is positioned at the upright position as illustrated in FIG. 5. The modular jack 10 has a length L that is measured in the thickness direction T1 of the electronic device A when the modular jack 10 is positioned at the rest position as illustrated in FIG. 1.

FIG. 2 is an exploded perspective view of the modular jack 10 and the attaching part 21. The attaching part 21 defines the cavity 24 at one side edge of the casing 20 of the electronic device A. The cavity 24 of the attaching part 21 is large enough to entirely accommodate the modular jack 10 in the rest position. In other words, as illustrated in FIG. 1, the thickness t of the casing 20, which is equal to the thickness of the attaching part 21, is less than the height H of the modular jack 10 and not greater the length L of the modular jack 10. Specifically, the relationship between the three dimensions H, L, and t is such that either H>L>t or H>L=t. Furthermore, the cavity 24 of the attaching part 21 has a length that is measured in a lengthwise direction T2 of the casing 20 that is perpendicular to the thickness direction T1 of the casing 20. The length of the cavity 24 is greater than the height H of the modular jack 10 such that the cavity can entirely accommodate the modular jack 10 in the rest position. Furthermore, the cavity 24 of the attaching part 21 has a width that is measured in a widthwise direction T3 of the casing 20 that is perpendicular to the thickness direction T1 and the lengthwise direction T2 of the casing 20. The width of the cavity 24 is substantially equal to a width of the modular jack 10 that is measured between a pair of outer side faces 12 (e.g., outer side surfaces) of the modular jack 10 such that the modular jack 10 is appropriately fitted to the cavity 24.

As illustrated in FIGS. 2 and 10, the modular jack 10 mainly has a hollow body portion 18 with the pair of outer side faces 12 that oppositely face each other, and a pair of circular projection axles 13 (e.g., circular protuberances) that is formed on the outer side faces 12 of the hollow body portion 18, respectively. The projection axles 13 form the pivot axis P1 of the modular jack 10. The modular jack 10 is a standardized RJ-45 modular jack. The hollow body portion 18 defines a fitting hole 11 to which a standardized RJ-45 modular plug 50 (e.g., opposing connector), is detachably coupled. An coupling direction Y in which the modular plug 50 is inserted in and removed from the fitting hole 11 is parallel to a length direction L1 of the modular jack 10 that is also parallel to the thickness direction T1 of the casing 20 when the modular jack 10 is positioned at the rest position as illustrated in FIGS. 1 and 2. The modular jack 10 and the modular plug 50 have pin electrodes 14 and 51 with necessary number of poles, respectively. Specifically, the modular jack 10 has eight pin electrodes 14, and the modular plug 50 also has eight pin electrodes 51. By inserting the modular plug 50 into the fitting hole 11, an appropriate electrical connection is established between the pin electrodes 14 of the modular jack 10 and the pin electrodes 51 of the modular plug 50.

As illustrated in FIG. 10, the pin electrodes 51 of the modular plug 50 are formed by a plate piece extending in the coupling direction Y of the modular plug 50. The pin electrodes 14 of the modular jack 10 are formed by a wire extending in the coupling direction Y of the modular jack 10. These pin electrodes 51 and 14 are placed in grooves 54 in the modular plug 50 and grooves 17 in the modular jack 10. The modular plug 50 also has an elastic operative piece 52 with an engaging part 53. The modular jack 10 has a step part 16 for interlocking with this engaging part 53. The step part 16 is provided in a top edge of the fitting hole 11 of the modular jack 10.

As illustrated in FIG. 2, the attaching part 21 of the casing 20 has a pair of inside wall faces 22 (e.g., inner side surfaces) that faces each other and defines the cavity 24 therebetween. The inside wall faces 22 have elongated bearing grooves 23 (or concavities), respectively. The bearing grooves 23 have ovular concavities extending in the lengthwise direction T2 of the attaching part 21. The projection axles 13 are formed at locations corresponding to the bearing grooves 23 on the outer side faces 12 facing outward in a width direction W1 of the modular jack 10, respectively. The projection axles 13 on both outer side faces 12 of the modular jack 10 are fitted respectively into the bearing grooves 23 on both inside wall faces 22 of the attaching part 21. As a result, the modular jack 10 is pivotally coupled to the attaching part 21 such that the modular jack 10 is movable between the rest position, as illustrated in FIG. 4, and the upright position, as illustrated in FIGS. 5 and 6. The modular jack 10 is also slidable relative to the attaching part 21 of the casing 20 along a lengthwise direction X (e.g., slide direction) of the elongated bearing grooves 23 that is parallel to the lengthwise direction T2 of casing 20 while the modular jack 10 is positioned at the rest position or at the upright position. The lengthwise direction X is also perpendicular to the pivot axis P1 of the modular jack 10.

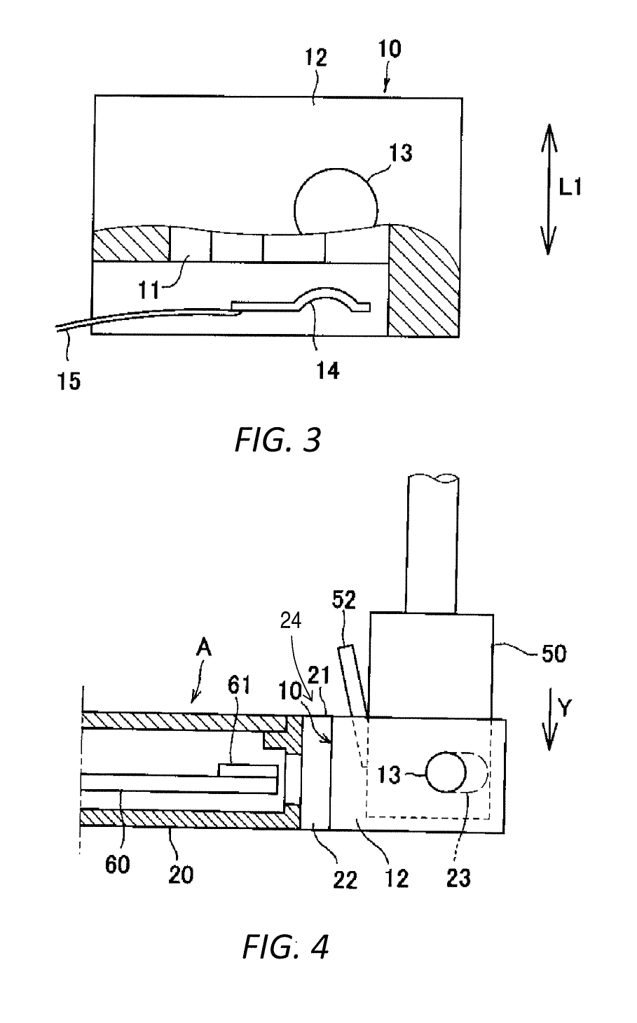

As illustrated in FIG. 3, the fitting hole 11 of the modular jack 10 extends through the entire length of the hollow body portion 18 in the length direction L1 of the modular jack 10. The pin electrodes 14 of the modular jack 10 are placed in a predetermined position in the fitting hole 11. The pin electrodes 14 are electrically coupled to signal wires 15.

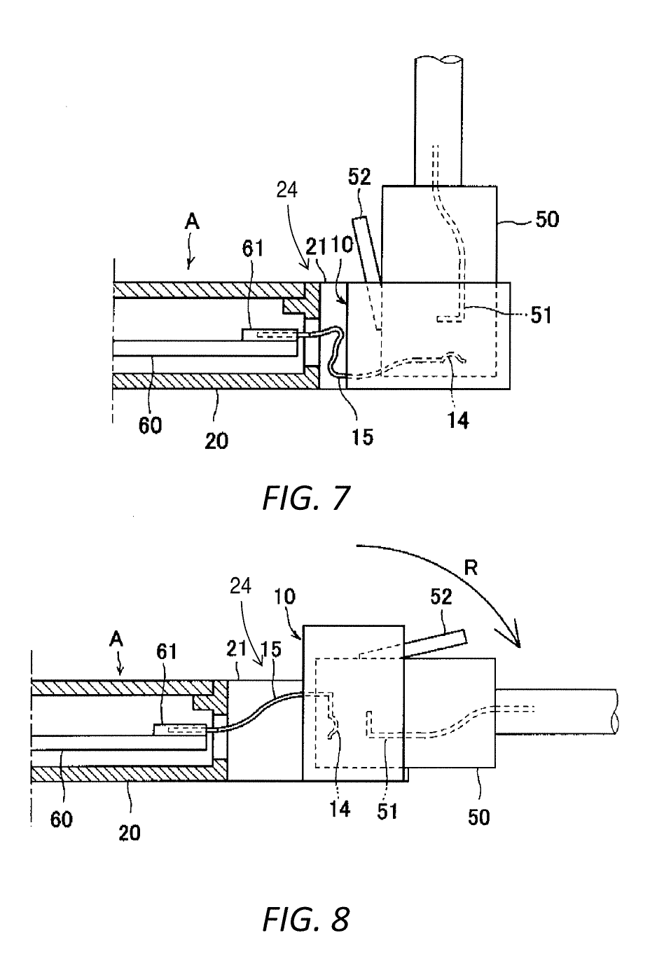

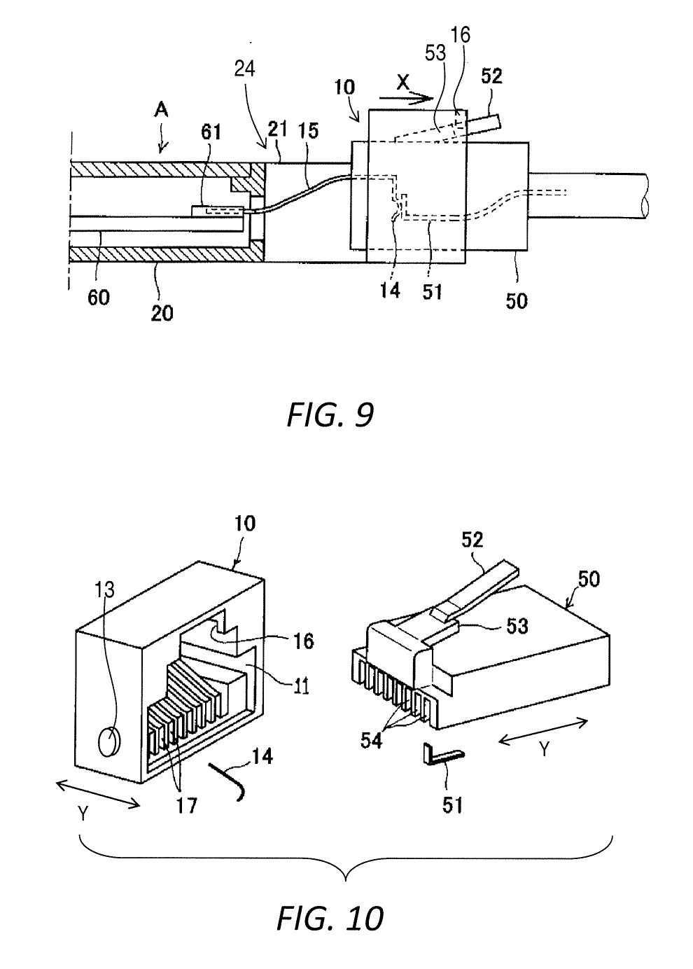

FIG. 4 illustrates a state in which the modular plug 50 is inserted into the modular jack 10 at the rest position. FIG. 5 illustrates a state in which the modular jack 10 is pivoted from the rest position to the upright position in a clockwise direction R when viewed in the pivot axis P1 of the modular jack 10. FIG. 6 illustrates a state in which the modular jack 10 slides relative to the casing 20 and the modular plug 50 while the modular jack 10 is positioned at the upright position. FIG. 7 illustrates a connection state between pin electrodes 14 and 51 of the modular jack 10 and the modular plug 50 when the modular jack 10 is positioned at the rest position as illustrated in FIG. 4. FIG. 8 illustrates a connection state between the pin electrodes 14 and 51 of the modular jack 10 and the modular plug 50 when the modular jack is positioned at the upright position as illustrated in FIG. 5. FIG. 9 illustrates a connection state between the pin electrodes 14 and 51 of the modular jack 10 and the modular plug 50 when the modular jack 10 slides relative to the casing 20 and the modular plug 50 while the modular jack 10 is positioned at the upright position as illustrated in FIG. 6.

As illustrated in FIGS. 1 and 4-9, the casing 20 of the electronic device A houses the circuit board 60 having an electronic circuit that is electrically connected to the pin electrodes 14 of the modular jack 10. The signal wires 15 extending out from the pin electrodes 14 of the modular jack 10 are electrically connected to a connector 61 mounted on the circuit board 60.

The modular plug 50 has a standardized shape and size. When the modular plug 50 is inserted up to an appropriate position in the modular jack 10 as the opposing connector, the step part 16 provided to a predetermined location of the modular jack 10 engages with the engaging part 53 of the modular plug 50. This prevents the modular plug 50 from falling out from the modular jack 10. The engaging part 53 of the modular plug 50 is provided to the elastic operative piece 52 of the modular plug 50. Therefore, the step part 16 of the modular jack 10 engages with the engaging part 53 of the modular plug 50 when the modular plug 50 is inserted up to the appropriate position. The engaged state between the engaging part 53 and the step part 16 is released by pushing down the elastic operative piece 52 of the modular plug 50.

When the modular jack 10 is not used, the modular jack 10 is kept in the rest position and accommodated in the cavity 24 of the attaching part 21 of the casing 20 as illustrated in FIG. 1. In this state, the modular jack 10 does not protrude from a top or bottom surface of the casing 20. Thus, the modular jack 10 is not a hindrance when the electronic device A is carried.

Referring to FIGS. 4 to 6, a connecting procedure for inserting the modular plug 50 into the modular jack 10 to exchange signals will be described in detail. Furthermore, referring to FIGS. 7-9, positional relationships between the pin electrodes 14 and 51 of the modular jack 10 and the modular plug 50 while the connecting procedure is conducted will also be described in detail.

Firstly, as illustrated in FIG. 4, the modular plug 50 is inserted into the modular jack 10 in the coupling direction Y while the modular jack 10 is positioned in the rest position and accommodated in the cavity 24 of the attaching part 21 of the electronic device A. This operation is performed to make it easier to pivot the modular jack 10 into the upright position in the next step, by causing the modular plug 50 to engage with the modular jack 10. Therefore, during this step, there is no need to cause the engaging part 53 of the modular plug 50 to engage with the step part 16 of the modular jack 10 to prevent the two from coming apart. During this step, the pin electrodes 14 and 51 of the modular jack 10 and modular plug 50 are separated from each other as illustrated in FIG. 7. Therefore, there is no exchange of signals between the modular jack 10 and modular plug 50.

After the modular plug 50 is inserted into the prone modular jack 10 as illustrated in FIG. 4, the modular plug 50 is pivoted in the clockwise direction R as illustrated in FIG. 5 by 90 degrees. Both the modular plug 50 and modular jack 10 pivot about the projection axles 13 (i.e., pivot axis P1) from the rest position to the upright position in the clockwise direction R. When this operation is performed, since the height H of the modular jack 10 is greater than the thickness t of the casing 20 and the attaching part 21 of the electronic device A, an end portion of the modular jack 10 protrudes relative to a top surface of the casing 20 or the attaching part 21 while the modular plug 50 protrudes out of the attaching part 21. The pin electrodes 14 and 51 of the modular jack 10 and modular plug 50 during this operation are also separated from each other as illustrated in FIG. 8. Therefore, there is no exchange of signals between the modular jack 10 and the modular plug 50.

Next, the modular jack 10 is slid outward of the attaching part 21 relative to the attaching part 21 in the lengthwise direction X of the bearing groove 23 as illustrated in FIG. 6. As a result, the modular plug 50 is inserted up to the appropriate position in the modular jack 10. During this operation, the projection axles 13 slide along the bearing grooves 23 of the attaching part 21, respectively. When the modular plug 50 is inserted up to the appropriate position in the modular jack 10, the step part 16 of the modular jack 10 engages with the engaging part 53 of the elastic operative piece 52 of the modular plug 50. Then, the step part 16 and the engaging part 53 lock together. As a result, the modular plug 50 is prevented from falling out of the modular jack 10. During this step, the pin electrodes 14 and 51 of the modular jack 10 and modular plug 50 contact with each other as illustrated in FIG. 9, which makes electrical conduction. In other words, the pin electrodes 14 and 51 makes an electrical connection in response to the modular jack 10 relatively sliding with respect to the modular plug 50 while the modular jack 10 is positioned at the upright position and the modular plug 50 is inserted into the modular jack 10. Therefore, the exchange of signals between the modular jack 10 and the modular plug 50 becomes enabled.

When the modular jack 10 returns to the rest position from the upright position illustrated in FIGS. 6 and 9 such that the modular jack 10 is accommodated in the cavity 24 of the attaching part 21 of the electronic device A, the engaged state (or locked state) between the engaging part 53 and the step part 16 is released by pushing down the elastic operative piece 52 of the modular plug 50, and the modular plug 50 is withdrawn slightly out of the modular jack 10, thereby causing the modular plug 50 to loosely engage with the modular jack 10. Then, the reverse steps of the steps described with reference to FIGS. 4 through 6 are performed.

The procedure described above is one example, and other procedure can also be possible. For example, when the modular jack 10 is positioned in the rest position and accommodated in the attaching part 21, the modular jack 10 can be manually pivoted into the upright position by an operator before the modular plug 50 is inserted into the modular jack 10. After the operator manually pivots the modular jack 10 into the upright position, a procedure can be performed in which the modular jack 10 is slid out of the attaching part 21 and the modular plug 50 is then inserted up to the appropriate position in the modular jack 10, resulting in the locked state described above.

With the modular jack 10 and the modular plug 50, by merely inserting the modular plug 50 into the modular jack 10, the pin electrodes 14 and 51 can contact with each other even if the step part 16 does not interlock with the engaging part 53. However, such an electronic connection is unstable and therefore is not actually used. In other words, with the standardized RJ-45 modular jack 10 and modular plug 50, the pin electrodes 14 and 51 can contact with each other during the steps illustrated in FIGS. 7 and 8. However, the modular jack 10 and the modular plug 50 are not used with such an electronic connection. The modular jack 10 and the modular plug 50 are used when the modular plug 50 is appropriately inserted until the engaging part 53 of the modular plug 50 interlocks with the step part 16 of the modular jack 10 as illustrated in FIG. 9.

Even when the modular jack 10 is positioned in the rest position and accommodated in the cavity 24 of the attaching part 21 of the electronic device A, a locked state can be enacted by interlocking the engaging part 53 with the step part 16 if the modular plug 50 can be inserted into the modular jack 10 up to the appropriate position. In this case, the pin electrodes 51 of the modular plug 50 stably contact with the pin electrodes 14 of the modular jack 10, respectively. Thus, the modular jack 10 and the modular plug 50 can be used to exchange signals while the modular jack 10 is positioned in the rest position.

However, depending on the type of the electronic device A or the condition of the location where the electronic device A is installed in another electronic device, the modular plug 50 will protrude out of the attaching part 21 and become a hindrance, or the modular plug 50 can not be inserted into the modular jack 10 while the modular jack 10 is accommodated in the rest position in the attaching part 21 of the electronic device A. Thus, it is beneficial to use the modular jack 10 and the modular plug 50 to exchange signals while the modular jack 10 is positioned at the upright position.

In this embodiment, the modular jack 10 is a RJ-45 modular jack used as Ethernet® connection terminal. However, the modular jack 10 can be any type of modular connectors or electrical connectors. Specifically, the modular jack 10 can be a RJ-11 modular jack that is used in phone lines.

With this electronic device A having the modular jack 10, since the length direction L1 of the modular jack 10 coincides with the thickness direction T1 of the attaching part 21 of the electronic device A when the modular jack 10 is positioned at the rest position. The modular jack 10 is configured such that the modular jack 10 does not protrude from the attaching part 21 in the thickness direction T1 when the modular jack 10 is positioned at the rest position. Therefore, the thickness t of the electronic device A is not affected by the size of the modular jack 10 that is attached to the attaching part 21 of the electronic device A, or particularly by the height H of the modular jack 10. The modular jack 10 can be utilized after pivoting from the rest position to the upright position, and by establishing an electrical connection between the pin electrodes 14 of the modular jack 10 and the pin electrode 51 of the modular plug 50 via an action for causing either the modular plug 50 or the modular jack 10 slide in the slide direction parallel to the lengthwise direction X relative to the other.

The electronic device A having the modular jack 10 is beneficial when the modular jack 10 can not be used while in the rest position. For example, when the electronic device A is a card-type communication device and is inserted into a slot of a notebook PC, if the modular plug 50 inserted into the modular jack 10 protrudes from the attaching part 21 of the electronic device A in the thickness direction T1 of the electronic device A, then the modular plug 50 is a hindrance when the electronic device A is inserted into the slot of the PC, or the electronic device A cannot be inserted into the slot of the PC. In such cases, With this electronic device A, the modular jack 10 in which the modular plug 50 is inserted is pivoted from the rest position to the upright position such that the modular plug 50 protrudes in a direction perpendicular to the thickness direction T1 of the attaching part 21 of the electronic device A. As a result, the modular plug 50 is no longer a hindrance, and it becomes possible to insert the electronic device A into the slot of the PC. Moreover, in this state, the electrical connection described above can be established.

When a casing of an electronic device is made small in thickness, if a standardized RJ-45 modular jack is attached in an upright orientation to a side face of the casing, then the modular jack protrudes from an attaching part in a thickness direction of the casing, making it inconvenient to carry the electronic device. Furthermore, the modular jack becomes an obstruction and may pose a hindrance for using the electronic device. However, with the electronic device A, the modular jack 10 can be laid prone and accommodated within the thickness t of the attaching part 21 even though the height H of the modular jack 10 is greater than the thickness t of the attaching part. Thus, the size of the modular jack 10 does not affect the size of the casing 20 of the electronic device A that has been made thinner. Accordingly, the size of the casing 20 of the electronic device A, particularly the thickness t of the casing 20 of the electronic device A, is no longer affected by the size of the modular jack 10. Thus, the casing 20 can be made thinner.

### General Interpretation of Terms

In understanding the scope of the present invention, the term “comprising” and its derivatives, as used herein, are intended to be open ended terms that specify the presence of the stated features, elements, components and groups, but do not exclude the presence of other unstated features, elements, components and groups. The foregoing also applies to words having similar meanings such as the terms, “including”, “having” and their derivatives. Also, the terms “part,” “section,” “portion,” “member” or “element” when used in the singular can have the dual meaning of a single part or a plurality of parts.

While a preferred embodiment have been chosen to illustrate the present invention, it will be apparent to those skilled in the art from these disclosures that various changes and modifications can be made herein without departing from the scope of the invention as defined in the appended claims. Furthermore, the foregoing descriptions of the preferred embodiment according to the present invention are provided for illustration only, and not for the purpose of limiting the invention as defined by the appended claims and their equivalents.

What is claimed is:

1. An electronic device comprising:
a circuit board;
a casing member accommodating the circuit board within the casing member, the casing member having an attaching part with a cavity;
a modular jack having a pin electrode that is electrically connected to the circuit board, the modular jack being pivotally arranged relative to the attaching part of the casing member about a pivot axis between a rest position and an upright position, the modular jack being arranged within the cavity of the attaching part of the casing member when the modular jack is positioned at the rest position, the modular jack being arranged to protrude relative to the cavity of the attaching part of the casing member when the modular jack is positioned at the upright position.

2. The electronic device according to claim 1, wherein
the cavity of the attaching part of the casing member has a depth that is measured in a first direction of the casing member, the depth of the cavity being at least a thickness of the modular jack that is measured in the first direction of the casing member when the modular jack is positioned at the rest position, the depth of the cavity being less than a height of the modular jack that is measured in the first direction of the casing member when the modular jack is positioned at the upright position.

3. The electronic device according to claim 1, wherein
the modular jack is slidable relative to the attaching part of the casing member in a slide direction that is perpendicular to the pivot axis of the modular jack.

4. The electronic device according to claim 3, wherein
the modular jack has a hollow body portion with a pair of outer side surfaces that oppositely face each other, and a pair of projection axles that is formed on the outer side surfaces of the hollow body portion, respectively, the projection axles forming the pivot axis of the modular jack, and
the attaching part of the casing has a pair of inner side surfaces that faces each other and defines the cavity therebetween, the inner side surfaces having elongated bearing grooves, respectively,
the projection axles of the modular jack being pivotally coupled to the elongated bearing grooves of the attaching part of the casing, respectively, the modular jack being slidable relative to the attaching part of the casing member in the slide direction that is parallel to a lengthwise direction of the elongated bearing grooves of the attaching part of the casing.

5. The electronic device according to claim 3, wherein
the modular jack is configured to be detachably connected to a modular plug with a pin electrode, the pin electrodes of the modular jack and the modular plug making an electrical connection in response to the modular jack relatively sliding with respect to the modular plug while the modular jack is positioned at the upright position and the modular plug is inserted into the modular jack.

6. The electronic device according to claim 1, wherein
the modular jack includes an RJ-45 modular jack.

7. The electronic device according to claim 2, wherein
the modular jack is slidable relative to the attaching part of the casing member in a slide direction that is perpendicular to the pivot axis of the modular jack.

8. The electronic device according to claim 7, wherein
the modular jack has a hollow body portion with a pair of outer side surfaces that oppositely face each other, and a pair of projection axles that is formed on the outer side surfaces of the hollow body portion, respectively, the projection axles forming the pivot axis of the modular jack, and
the attaching part of the casing has a pair of inner side surfaces that faces each other and defines the cavity therebetween, the inner side surfaces having elongated bearing grooves, respectively,
the projection axles of the modular jack being pivotally coupled to the elongated bearing grooves of the attaching part of the casing, respectively, the modular jack being slidable relative to the attaching part of the casing member in the slide direction that is parallel to a lengthwise direction of the elongated bearing grooves of the attaching part of the casing.

9. The electronic device according to claim 7, wherein
the modular jack is configured to be detachably connected to a modular plug with a pin electrode, the pin electrodes of the modular jack and the modular plug making an electrical connection in response to the modular jack relatively sliding with respect to the modular plug while the modular jack is positioned at the upright position and the modular plug is inserted into the modular jack.

10. The electronic device according to claim 2, wherein
the modular jack includes an RJ-45 modular jack.
